(19) United States
(12) Patent Application Publication
(10) Pub. No.: US 2019/0199315 A1
(43) Pub. Date: Jun. 27, 2019

(54) VIBRATOR DEVICE, ELECTRONIC APPARATUS AND VEHICLE

(71) Applicant: SEIKO EPSON CORPORATION, Tokyo (JP)

(72) Inventors: Shiro MURAKAMI, Shiojiri-shi (JP); Atsushi MATSUO, Shiojiri-shi (JP); Shinya AOKI, Minowa-machi (JP); Masashi SHIMURA, Chino-shi (JP); Ryuta NISHIZAWA, Nagano-shi (JP)

(73) Assignee: SEIKO EPSON CORPORATION, Tokyo (JP)

(21) Appl. No.: 16/229,618

(22) Filed: Dec. 21, 2018

(30) Foreign Application Priority Data
Dec. 25, 2017 (JP) 2017-247353

(51) Int. Cl. H03H 9/02; H03H 9/05; H03H 9/10; H03H 9/19; H03B 5/04

(52) U.S. Cl. CPC H03H 9/02102; H03H 9/02023; H03H 9/02133; H03H 9/0519; H03B 5/326; H03H 9/1021; H03H 9/19; H03B 5/04; H03H 9/0552

(57) ABSTRACT

A vibrator device includes a base; a circuit element attached to the base; a vibrator element attached to the circuit element; and a plurality of temperature sensors arranged in the circuit element, in which the circuit element includes a first connecting terminal connected to the base, a second connecting terminal connected to the vibrator element, and at least one circuit of an output buffer circuit, a power supply circuit, and a phase-locked loop circuit, and the shortest distance between each of the plurality of temperature sensors and the first connecting terminal or the second connecting terminal is shorter than the shortest distance between each of the temperature sensors and the at least one circuit.

### BACKGROUND

### 1. Technical Field

The present invention relates to a vibrator device, an electronic apparatus, and a vehicle.

### 2. Related Art

In the related art, for example, as represented by a quartz crystal oscillator, a vibrator device including a vibrator element and a circuit element has been known. A temperature-compensated oscillator disclosed in JP-A-2007-295302 includes a container main body made of concave ceramic having an inner wall stepped portion, an IC chip integrated with an oscillation circuit and a temperature-compensated mechanism fixed to an inner bottom surface of the container main body using a bump, a quartz crystal element fixed to the inner wall stepped portion of the container main body using a conductive adhesive. Here, in the IC chip, the temperature sensor of the temperature-compensated mechanism is disposed in the vicinity of an IC terminal.

However, in the temperature-compensated oscillator disclosed in JP-A-2007-295302, since quartz crystal element and the IC chip are respectively fixed to the container main body, it is difficult for a temperature sensor provided in the IC chip to detect the temperature of the quartz crystal element with high accuracy, and thereby it is not possible to realize a sufficient temperature compensation function.

### SUMMARY

An advantage of some aspects of the invention is to provide a vibrator device capable of improving temperature compensation performance, and to provide an electronic apparatus and a vehicle provided with the vibrator device.

The invention can be implemented as the following application examples or embodiments.

A vibrator device according to an application example includes abase; a circuit element attached to the base; a vibrator element attached to the circuit element; and a plurality of temperature sensors arranged in the circuit element, in which the circuit element includes a first connecting terminal connected to the base, a second connecting terminal connected to the vibrator element, and at least one circuit of an output buffer circuit, a power supply circuit, and a phase-locked loop (PLL) circuit, and the shortest distance between each of the plurality of temperature sensors and the first connecting terminal or the second connecting terminal is shorter than the shortest distance between each of the temperature sensors and the at least one circuit.

According to such a vibrator device, since the vibrator element is attached to the circuit element, it is possible to detect the temperature of the vibrator element with high accuracy (high sensitivity) by using a temperature sensor disposed in the circuit element. For this reason, the temperature compensation performance of the vibrator device can be improved by using the detection result of the temperature sensor. In addition, since there are a plurality of the temperature sensors, it is possible to detect the temperature distribution of the circuit element by using the plurality of temperature sensors and perform more appropriate temperature compensation using the detection result.

Further, when the temperature sensor is disposed at a position closer to the connecting terminal than the output buffer circuit, the power supply circuit, and the phase-locked loop circuit which are the heat sources in the circuit element, it is possible to further reduce the heat effect of the circuit element, and improve the temperature measurement accuracy of the vibrator element. Here, the phrase “connected to the base” includes not only a case of being directly connected to the base but also a case of being connected to the base via a member such as a metal bump. Similarly, the phrase “connected to the vibrator element” includes not only a case of being directly connected to the vibrator element but also a case of being connected to the vibrator element via a member such as a metal bump or a relay substrate.

In the vibrator device according to the application example, at least two of the plurality of temperature sensors may be arranged at different positions when viewed from a direction in which the circuit element and the vibrator element are arranged.

With this configuration, it is possible to detect the temperature distribution in the in-plane direction of the circuit element. Therefore, more appropriate temperature compensation can be performed using the detection result.

In the vibrator device according to the application example, the plurality of temperature sensors may include a first temperature sensor disposed on an active surface side of the circuit element, and a second temperature sensor disposed on a side opposite to the active surface side of the circuit element.

With this configuration, it is possible to detect the temperature distribution in a thickness direction of the circuit element. Therefore, more appropriate temperature compensation can be performed using the detection result.

The vibrator device according to the application example may further includes a relay substrate disposed between the vibrator element and the circuit element; a first bonding material that bonds the base and the circuit element to each other; a second bonding material that bonds the circuit element and the relay substrate to each other; and a third bonding material that bonds the relay substrate and the vibrator element to each other.

With this configuration, the stress generated in the vibrator element can be reduced. Therefore, it is possible to improve the characteristics such as the frequency-temperature characteristics of the vibrator device.

In the vibrator device according to the application example, each of the first bonding material, the second bonding material, and the third bonding material may be a metal bump.

With this configuration, heat conduction can be efficiently performed between the vibrator element and the circuit element. For this reason, the temperature sensor can be used to detect the temperature of the vibrator element with higher accuracy. In addition, it is possible to mount the vibrator element and the circuit element on the package without using a resin material. Therefore, even if a heat treatment is performed after the package is sealed, problems due to outgassing do not occur in the package. Since the vibrator element is attached to the circuit element via the relay substrate, the stress generated in the vibrator element can be reduced even with metal bumps.

In the vibrator device according to the application example, the first bonding material and the second bonding material may be disposed on the active surface of the circuit element, and at least one of the plurality of temperature sensors is disposed on the active surface of the circuit element.

With this configuration, there is no need to provide a structure like a Si through electrode in the circuit element, and cost reduction of the circuit element can be achieved. Further, by using the temperature sensors arranged on the active surface side of the circuit element, it is possible to detect the temperature of the vibrator element with higher accuracy.

In the vibrator device according to the application example, one of the first bonding material and the second bonding material may be disposed on the active surface of the circuit element, and the other one is disposed on a surface opposite to the active surface of the circuit element, and at least one of the plurality of temperature sensors is disposed on the second bonding material side of the circuit element.

With this configuration, the circuit element and the relay substrate can be stacked and mounted on the package from the same side. Therefore, there is an advantage that these implementations are simplified. Further, by using the temperature sensors arranged on the second bonding material side of the circuit element, it is possible to detect the temperature of the vibrator element with higher accuracy.

In the vibrator device according to the application example, the second bonding material may be disposed on one surface of the relay substrate, and the third bonding material is disposed on the other surface of the relay substrate.

With this configuration, the relay substrate and the vibrator element can be stacked and mounted on the circuit element from the same side. Therefore, there is an advantage that these implementations are simplified.

An electronic apparatus according to an application example includes the vibrator device according to the application example.

According to such an electronic apparatus, the characteristics of the electronic apparatus can be improved by using excellent characteristics of the vibrator device.

A vehicle according to an application example includes the vibrator device according to the application example.

According to such a vehicle, the characteristics of the vehicle can be improved by using excellent characteristics of the vibrator device.

### BRIEF DESCRIPTION OF THE DRAWINGS

The invention will be described with reference to the accompanying drawings, wherein like numbers reference like elements.

FIG. 1 is a longitudinal sectional view (a sectional view along an αγ plane) illustrating a vibrator device (oscillator) according to a first embodiment of the invention.

FIG. 2 is a plan view (view seen from +γ direction side) of the vibrator device as illustrated in FIG. 1.

FIG. 3 is a plan view (view seen from −γ direction side) of a circuit element included in the vibrator device as illustrated in FIG. 1.

FIG. 4 is a plan view (view seen from −γ direction side) of a relay substrate included in the vibrator device as illustrated in FIG. 1.

FIG. 5 is a plan view (view seen from −γ direction side) illustrating Modification Example 1 of the relay substrate.

FIG. 6 is a plan view (view seen from −γ direction side) illustrating Modification Example 2 of the relay substrate.

FIG. 7 is a longitudinal sectional view (a sectional view along an αγ plane) illustrating a vibrator device (oscillator) according to a second embodiment of the invention.

FIG. 8 is a perspective view illustrating a configuration of a mobile type (or notebook type) personal computer which is an example of an electronic apparatus according to the invention.

FIG. 9 is a perspective view illustrating a configuration of a smartphone which is an example of the electronic apparatus according to the invention.

FIG. 10 is a perspective view illustrating a configuration of a digital still camera which is an example of the electronic apparatus according to the invention.

FIG. 11 is a perspective view illustrating an automobile which is an example of a vehicle according to the invention.

### DESCRIPTION OF EXEMPLARY EMBODIMENTS

Hereinafter, a vibrator device, an electronic apparatus, and a vehicle according to the invention will be described in detail based on preferred embodiments illustrated in the drawings.

### Vibrator Device

### First Embodiment

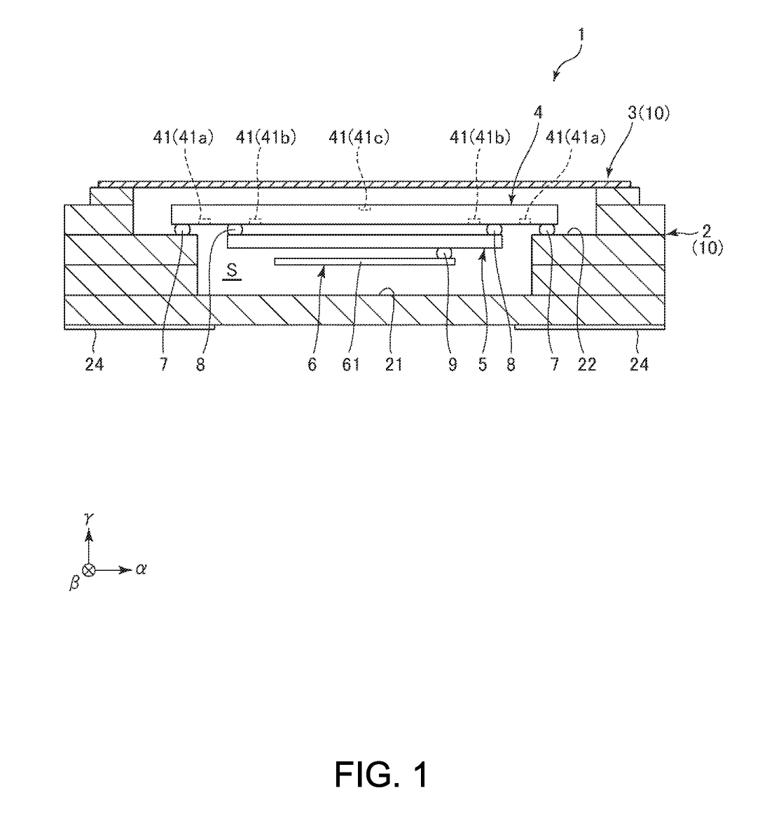

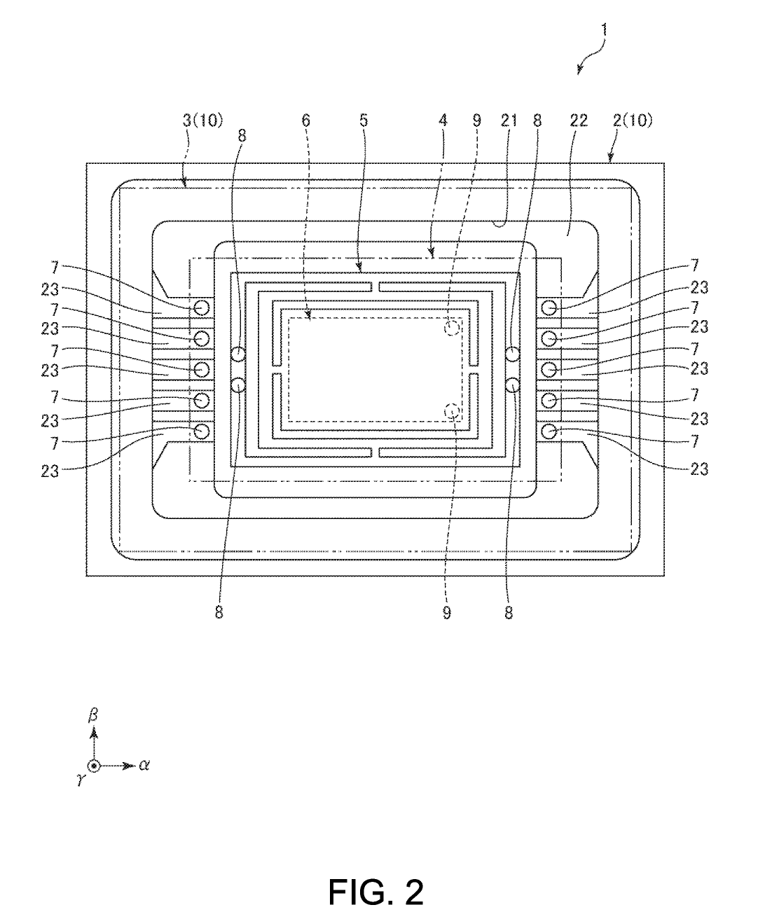

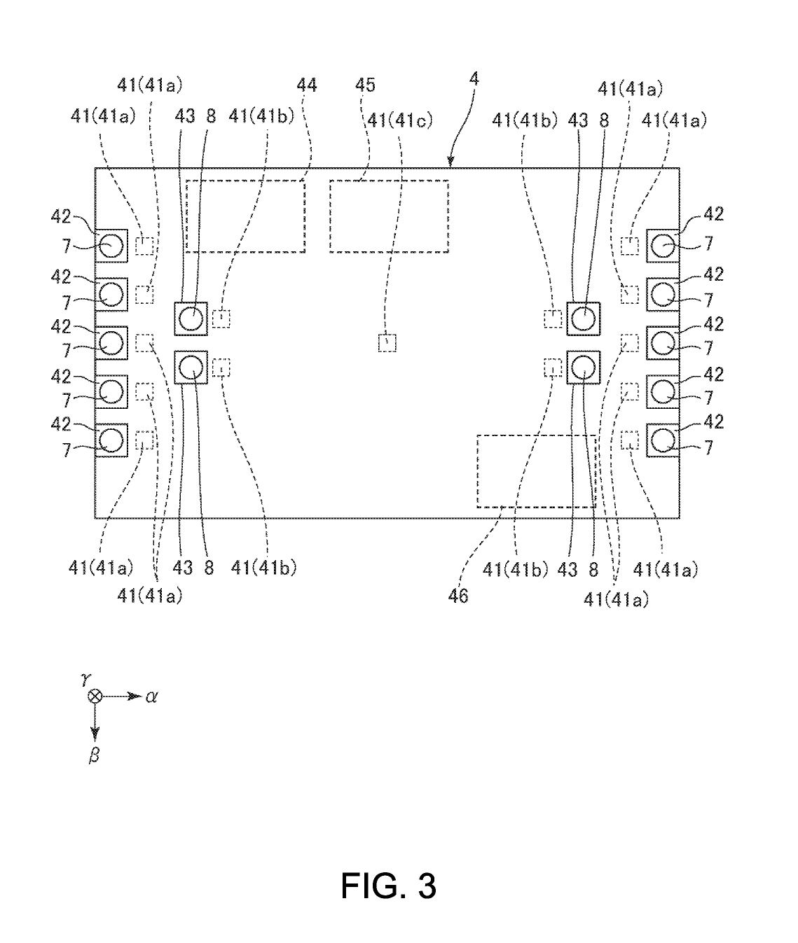

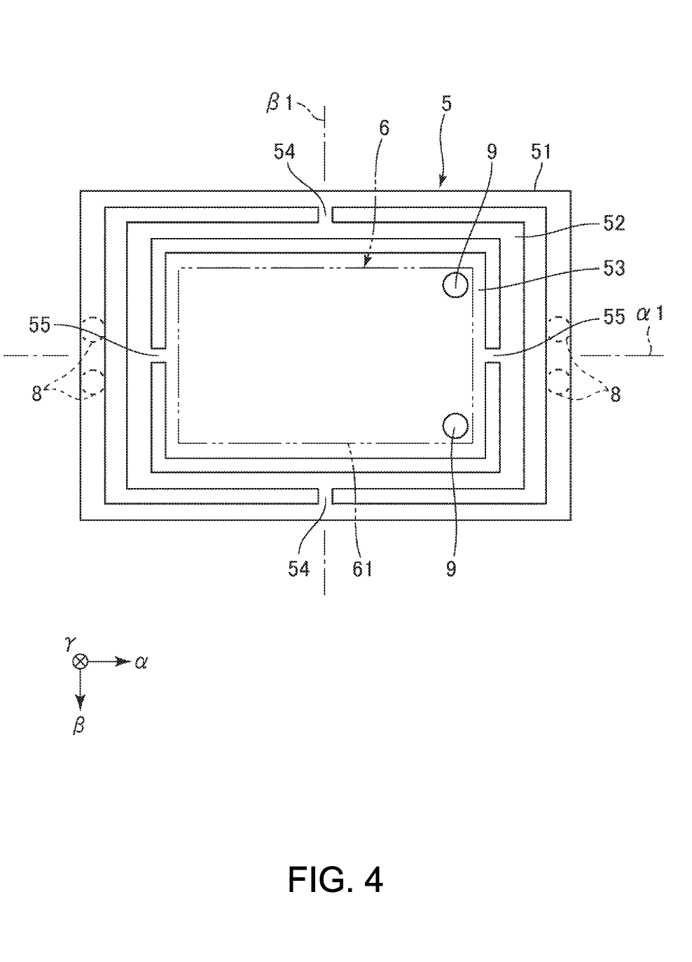

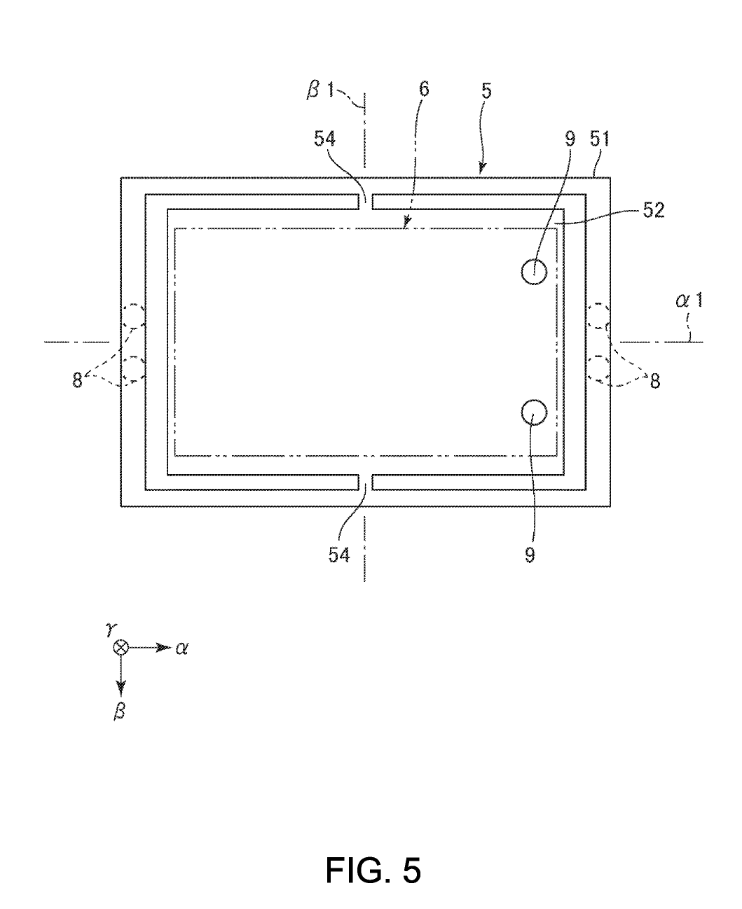

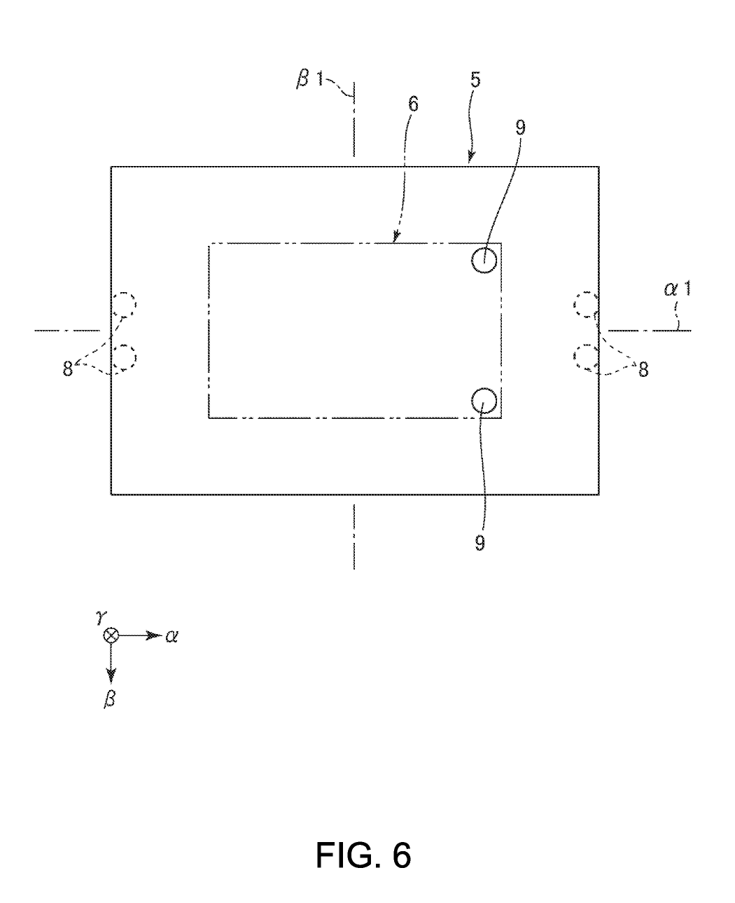

FIG. 1 is a longitudinal sectional view (a sectional view along an αγ plane) illustrating a vibrator device (oscillator) according to a first embodiment of the invention. FIG. 2 is a plan view (view seen from +γ direction side) of the vibrator device as illustrated in FIG. 1. FIG. 3 is a plan view (view seen from −γ direction side) of a circuit element as illustrated in FIG. 1. FIG. 4 is a plan view (view seen from −γ direction side) of a relay substrate as illustrated in FIG. 1. FIG. 5 is a plan view (view seen from −γ direction side) illustrating Modification Example 1 of the relay substrate. FIG. 6 is a plan view (view seen from −γ direction side) illustrating Modification Example 2 of the relay substrate.

In the following description, for convenience of explanation, explanation will be made by appropriately using three axes of an α axis, a β axis, and a γ axis which are orthogonal to each other. In the following description, a direction parallel to the α axis is referred to as “α direction”, α direction parallel to the β axis is referred to as “β direction”, and α direction parallel to the γ axis is referred to as “γ direction”. In the following description, in the drawings, the leading end side of the arrow indicating each axis of the α axis, the β axis, and the γ axis is “+” and the base end side thereof is “−”. Also, the upper side (+γ direction side) in FIG. 1 is referred to as “above” and the lower side (−γ direction side) as “under”. In addition, viewing from the γ direction is also referred to as “plan view”. Further, in FIG. 2, for the sake of convenience of the explanation, the interior of a base 2 is illustrated through a lid 3 in a transparent manner.

A vibrator device 1 illustrated in FIG. 1 is a quartz crystal oscillator. The vibrator device 1 is provided with a base 2 (base body), a lid 3, a circuit element 4, a relay substrate 5, a vibrator element 6, metal bumps 7, 8, and 9.

Here, the base 2 and the lid 3 constitute a package 10 having a space S storing the circuit element 4, the relay substrate 5, and the vibrator element 6. In the space S of this package 10, the circuit element 4, the relay substrate 5, and the vibrator element 6 are arranged (stacked) in this order from the +γ direction side to the −γ direction side.

The metal bump 7 (first metal bump: first bonding material) bonds the base 2 and the circuit element 4, and the circuit element 4 is attached to the base 2 via the metal bump 7. The metal bump 8 (second metal bump: second bonding material) bonds the circuit element 4 and the relay substrate 5, and the relay substrate 5 is attached to the circuit element 4 via the metal bump 8. The metal bump 9 (third metal bump: third bonding material) bonds the relay substrate 5 and the vibrator element 6, and the vibrator element 6 is attached to the relay substrate 5 via the metal bump 9. In addition, the circuit element 4 includes a plurality of temperature sensors 41.

In this manner, in the vibrator device 1, the vibrator element 6 is attached to the circuit element 4 (attached via the relay substrate 5 in this embodiment), and thus it is possible to detect the temperature of the vibrator element 6 with high accuracy by using a temperature sensor 41 disposed in the circuit element 4. For this reason, the temperature compensation performance of the vibrator device can be improved by using the detection result of the temperature sensor 41. In addition, since there are a plurality of the temperature sensors 41, it is possible to detect the temperature distribution of the circuit element 4 by using the plurality of temperature sensors 41 and perform more appropriate temperature compensation using the detection result. Hereinafter, each part of such a vibrator device 1 will be described.

### Package

The package 10 includes a box-shaped base 2 having a recessed portion 21 opening to a top surface and a plate-shaped lid 3 bonded to the base 2 and closing an opening (upper opening) of the recessed portion 21, and forms the space S between the base 2 and the lid 3 as an airtight space for storing the circuit element 4, the relay substrate 5, and the vibrator element 6. This space S may be in a depressurized (vacuum) state or an inert gas such as nitrogen, helium, or argon may be sealed.

The constituent material of the base 2 is not particularly limited, and a material that has insulating properties and is suitable for making the space S an airtight space can be used. Examples thereof include various ceramics such as oxide ceramics such as alumina, silica, titania, and zirconia, nitride ceramics such as silicon nitride, aluminum nitride, and titanium nitride, and carbide ceramics such as silicon carbide.

The base 2 has a stepped portion 22 provided so as to surround the outer periphery of the bottom surface of the recessed portion 21 above the bottom surface of the recessed portion 21. As illustrated in FIG. 2, a plurality (ten in the drawing) of connecting electrodes 23 to be electrically connected to the circuit element 4 are provided on the upper surface of the stepped portion 22. These connecting electrodes 23 are electrically connected to a plurality of external mounting electrodes 24 (refer to FIG. 1) provided on the lower surface of the base 2 via through electrodes (not shown) penetrating the base 2, respectively.

The constituent materials of the connecting electrodes 23, the external mounting electrode 24, and the through electrode are not particularly limited, and examples thereof include metallic materials such as gold (Au), a gold alloy, platinum (Pt), aluminum (Al), an aluminum alloy, silver (Ag), a silver alloy, chromium (Cr), a chromium alloy, nickel (Ni), copper (Cu), molybdenum (Mo), niobium (Nb), tungsten (W), iron (Fe), titanium (Ti) cobalt (Co), zinc (Zn), and zirconium (Zr).

The lid 3 is bonded to the upper end face of such abase 2 by, for example, seam welding. Here, a bonding member such as a seal ring for bonding these may be interposed between the base 2 and the lid 3. The constituent material of the lid 3 is not particularly limited, and a metallic material is preferably used, and among them, it is preferable to use a metallic material having a linear expansion coefficient close to that of the constituent material of the base 2. Therefore, for example, in a case where the base 2 is a ceramic substrate, it is preferable to use an alloy such as Kovar as the constituent material of the lid 3.

### Circuit Element

The circuit element 4 is an integrated circuit element having a function of driving the vibrator element 6 to oscillate and a function (temperature compensation function) of correcting the frequency-temperature characteristics of the oscillation frequency. The circuit element 4 includes the plurality of temperature sensors 41, a plurality of terminals 42 (first connecting terminals), a plurality of terminals 43 (second connecting terminals), an output buffer circuit 44, a power supply circuit 45, a phase-locked loop circuit 46, a drive circuit (not shown), and a temperature compensation circuit (not shown). Here, in the circuit element 4, the drive circuit drives the vibrator element 6 to oscillate the vibrator element 6 and output a signal of a desired frequency. Further, the circuit element 4 corrects the frequency-temperature characteristic of the output signal of the circuit element 4 according to the output signal of the temperature sensor 41. The output buffer circuit 44 reduces the fluctuation of the oscillation frequency. The power supply circuit 45 supplies electric power to each part of the circuit element 4. The phase-locked loop circuit 46 performs frequency multiplication so as to obtain a desired oscillation frequency. Note that, the circuit element 4 may have at least one of the output buffer circuit 44, the power supply circuit 45, and the phase-locked loop circuit 46.

The plurality of terminals 42 and the plurality of terminals 43 illustrated in FIG. 3 are disposed on the lower surface (the lower surface in FIG. 1), which is the active surface of the circuit element 4. The plurality of terminals 42 are terminals for connecting to the plurality of connecting electrodes 23 of the base 2 described above, and are provided corresponding to the plurality of connecting electrodes 23. As illustrated in FIG. 3, the plurality of terminals 42 are arranged side by side in the β direction at both end portions in the α direction of the circuit element 4. Each of the plurality of terminals 42 is bonded to the corresponding connecting electrode 23 via the metal bump 7. As a result, the circuit element 4 is attached to the base 2, and the circuit element 4 and the base 2 are electrically connected to each other. Further, the plurality of terminals 43 are terminals for connecting to the relay substrate 5, and include terminals electrically connected to a pair of excitation electrodes (pad electrodes) of the vibrator element 6 described later via the relay substrate 5. As illustrated in FIG. 3, the plurality of terminals 43 are arranged side by side in the β direction at both end portions in the α direction of the circuit element 4 inside the plurality of terminals 42. Each of the plurality of terminals 43 is bonded to the relay substrate 5 via the metal bump 8. As a result, the relay substrate 5 is attached to the circuit element 4, and the circuit element 4 and the relay substrate 5 are electrically connected to each other.

As illustrated in FIG. 3, the plurality of temperature sensors 41 are arranged at different positions of the circuit element 4 in plan view. This makes it possible to detect the temperature distribution in the in-plane direction of the circuit element 4 by using the plurality of temperature sensors 41. Here, the plurality of temperature sensors 41 include a plurality of temperature sensors 41a and a plurality of temperature sensors 41b arranged on the lower surface (active surface) side of the circuit element 4, and a temperature sensor 41c disposed on the upper surface side of the circuit element 4. When the temperature sensors 41 are provided on both sides of the circuit element 4 in this manner, the temperature distribution in the thickness direction of the circuit element 4 can also be detected using the plurality of temperature sensors 41. Note that, the temperature sensor 41c disposed on the side opposite to the active surface of the circuit element 4 is, for example, a thin film thermistor.

The plurality of temperature sensors 41a are provided corresponding to the plurality of terminals 42 or the plurality of metal bumps 7 described above. In order to detect the temperature of the corresponding terminal 42 or the metal bump 7, each of the temperature sensors 41a is disposed in the vicinity of the corresponding terminal 42 or the metal bump 7 (position closer than a terminal or a metal bump other than the corresponding terminal 42 or the metal bump 7). In addition, as described above, in order to detect the temperature of the corresponding terminal 42 without receiving the influence of heat from the output buffer circuit 44, the power supply circuit 45, and the phase-locked loop circuit 46 which are heat sources as much as possible, each temperature sensor 41a is disposed closer to the corresponding terminal 42 than these heating sources.

The plurality of temperature sensors 41b are provided corresponding to the plurality of terminals 43 or the plurality of metal bumps 8 described above. In order to detect the temperature of the corresponding terminal 43 or the metal bump 8, each of the temperature sensors 41b is disposed in the vicinity of the corresponding terminal 43 or the metal bump 8 (position closer than a terminal or a metal bump other than the corresponding terminal 43 or the metal bump 8). In addition, as described above, in order to detect the temperature of the corresponding terminal 43 without receiving the influence of heat from the output buffer circuit 44, the power supply circuit 45, and the phase-locked loop circuit 46 which are heat sources as much as possible, each temperature sensor 41b is disposed closer to the corresponding terminal 43 than these heating sources.

The temperature sensor 41c is disposed at the center of the circuit element 4 in plan view. The temperature sensor 41c is disposed at a position closest to the lid 3 among the plurality of temperature sensors 41. As a result, it is possible to suitably detect the temperature change of the circuit element 4 due to the heat from the lid 3 using the temperature sensor 41c.

Note that, the arrangement of the temperature sensors 41 illustrated in the drawing is merely an example, and the invention is not limited thereto. For example, in the drawing, the temperature sensors 41a are arranged so as not to overlap the corresponding terminal 42 or the metal bump 7 in plan view, but may be arranged so as to overlap the corresponding terminal 42 or the metal bump 7. Similarly, the temperature sensors 41b may be arranged so as to overlap the corresponding terminal 43 or the metal bump 8 in plan view. In addition, it suffices that the circuit element 4 has the plurality of temperature sensors 41, and apart of the plurality of temperature sensors 41 described above may be omitted, and another temperature sensor may added to the circuit element 4. Although the temperature sensor 41c is disposed at the center of the circuit element 4 in plan view, the temperature sensor 41c is not limited to this, and may be disposed so as to overlap the temperature sensor 41a or 41b in plan view, for example.

### Relay Substrate

As illustrated in FIG. 1, the relay substrate 5 is bonded to the lower surface (the surface on the −γ direction side) of the circuit element 4 by a plurality of the metal bumps 8. The vibrator element 6 is bonded to the surface of the relay substrate 5 on the side opposite to the circuit element 4 via a metal bump 9. Here, wiring (not shown) provided corresponding to a pair of excitation electrodes (pad electrodes) of the vibrator element 6 described later is disposed on the relay substrate 5, and the corresponding metal bumps 8 and 9 are connected to each other through the corresponding wiring.

As illustrated in FIG. 4, the relay substrate 5 of this embodiment has a gimbal shape. The relay substrate 5 includes a frame-like first part 51, a frame-like second part 52 disposed inside the first part 51, a third part 53 disposed inside the second part 52, a first beam portion 54 supporting the second part 52 with respect to the first part 51 so as to be swingable about the first axis β1, a second beam portion 55 supporting the third part 53 with respect to the second part 52 so as to be swingable about the second axis al intersecting with the first axis β1. Here, the first part 51, the second part 52, the third part 53, the first beam portion 54, and the second beam portion 55 are integrally formed.

In plan view, the first part 51 is a rectangle whose outer and inner circumferences are the α direction as a longitudinal direction, and is disposed so as to overlap the plurality of terminals 43 of the circuit element 4. In plan view, the second part 52 has a shape (that is, a rectangle) along the inner periphery of the first part 51 in the outer periphery and the inner periphery, and is disposed inside the first part 51 to be spaced apart from the first part 51. In plan view, the third part 53 has a shape (that is, a rectangle) along the inner periphery of the second part 52, and is disposed inside the second part 52 to be spaced apart from the second part 52. In plan view, the first beam portion 54 is disposed between the first part 51 and the second part 52 and has a shape extending along the first axis β1, and the first part 51 and the second part 52 are connected to each other. In plan view, the second beam portion 55 is disposed between the second part 52 and the third part 53 and has a shape extending along the second axis α1, and the second part 52 and the third part 53 are connected to each other.

In such a relay substrate 5, the second part 52 is capable of swinging around the first axis β1 with respect to the first part 51 with elastic deformation of the first beam portion 54, and the third part 53 is capable of swinging around the second axis α1 with respect to the second part 52 with elastic deformation of the second beam portion 55. Therefore, the third part 53 is capable of swinging about both the first axis β1 and the second axis α1 with respect to the first part 51. Here, the circuit element 4 is bonded to the first part 51 via the metal bump 8, whereas the third part 53 is bonded to the vibrator element 6 via the metal bump 9. With this, the stress generated in the vibrator element 6 can be further reduced. Further, vibration from the package 10 is less likely to be transmitted to the vibrator element 6, and as a result, vibration resistance characteristics can be improved.

The shape of each part of the relay substrate 5 is not limited to the shape illustrated in the drawings. For example, the outer peripheries and the inner peripheries of the first part 51, the second part 52, and the third part 53 in plan view may have other polygonal shapes such as a square shape and a hexagonal shape, respectively. In addition, each of the first beam portion 54 and the second beam portion 55 may have a bent portion or a branched part in the middle thereof, or may be disposed at a position displaced from the first axis β1 or the second axis α1. Further, for example, as illustrated in FIG. 5, the relay substrate 5 does not need to have a gimbal shape. For example, as illustrated in FIG. 5, the above-described second beam portion 55 may be omitted, and the second part 52 and the third part 53 may be in the form of an integrated single plate. Further, as illustrated in FIG. 6, the relay substrate 5 may be in the form of a single board.

Here, the widths of the first beam portion 54 and the second beam portion 55 are preferably smaller than the thickness of the relay substrate 5. With this, the stress generated in the vibrator element 6 can be suitably reduced.

The thickness of the relay substrate 5 varies depending on the shape of the relay substrate 5 in plan view, and is not particularly limited, but is preferably larger than the thickness of the vibrator element 6 and smaller than the thickness of the circuit element 4. More specifically, it is preferably 1.5 times or more the thickness of the vibrator element 6 and 0.8 times or less the thickness of the circuit element 4. With this, the stress generated in the vibrator element 6 can be suitably reduced.

Although the constituent material of the relay substrate 5 is not particularly limited, it is preferable to use a material having a linear expansion coefficient close to that of the constituent material of the vibrator element 6, specifically, it is preferable to use quartz crystal. With this, it is possible to reduce the stress generated in the vibrator element 6 due to the difference in the linear expansion coefficient between the relay substrate 5 and the vibrator element 6. In particular, in a case where the relay substrate 5 is made of quartz crystal, the relay substrate 5 has a spread in a XY plane defined by the Y axis (machine axis) and the X axis (electric axis) which are the quartz crystal axes of the quartz crystal substrate, and is preferably in a form of a plate having a thickness in the direction of the Z axis (optical axis). That is, it is preferable that the relay substrate 5 is formed of a Z-cut quartz crystal board. As a result, it is possible to easily obtain the relay substrate 5 having high dimensional accuracy by wet etching. Note that, the Z-cut quartz crystal board includes a quartz crystal board having a cut angle such that the plane orthogonal to the Z axis is rotated in a range of 0 to 10 degrees around at least one of the X axis and the Y axis as the principal plane.

### Vibrator Element

The vibrator element 6 is an element that excites thickness sliding vibration. The vibrator element 6 includes a quartz crystal substrate 61, a pair of excitation electrodes (not shown) disposed on both surfaces of the quartz crystal substrate 61, and a pair of pad electrodes (not shown) electrically connected to the pair of excitation electrodes disposed on one surface (upper surface) of the quartz crystal substrate 61. In the vibrator element 6, when a periodically changing voltage is applied between the pair of excitation electrodes through the pair of pad electrodes, thickness sliding vibration is excited at a desired frequency in a predetermined portion of the quartz crystal substrate 61.

Here, the quartz crystal belongs to the trigonal system and has an X axis, a Y axis and a Z axis orthogonal to each other as crystal axes. The X axis, the Y axis, and the Z axis are referred to as an electric axis, a mechanical axis, and an optical axis, respectively. The quartz crystal substrate 61 is a “rotated Y-cut quartz crystal substrate” cut along a plane obtained by rotating the XZ plane (a plane orthogonal to the Y axis) around the X axis by a predetermined angle θ. By using an AT-cut quartz crystal substrate which is a rotated Y-cut quartz crystal substrate of θ=35° 15′ as the quartz crystal substrate 61, the vibrator element 6 having excellent temperature characteristics is obtained. Note that, the quartz crystal substrate 61 is not limited to the AT-cut quartz crystal substrate as long as it can excite thickness shear vibration, and for example, a BT cut or SC cut quartz crystal substrate may be used.

The quartz crystal substrate 61 has a rectangular shape whose longitudinal direction is the α direction in plan view. The shape of the vibrator element 6 in plan view is not limited to the above-described shape as long as it has a shape obtained by chamfering one corner of a circle or rectangle shape. Although the thickness of the vibrator element 6 is constant in the drawing, it is not limited thereto, and it may be, for example, a so-called mesa type or an inverted mesa type.

As the structure of the excitation electrode and the pad electrode used for the vibrator element 6, a known electrode material can be used, but it is not particularly limited thereto. For example, metal coating is cited which uses metal such as Au (gold) and Al (aluminum) or an alloy containing Au and Al as a main component on a base layer such as Cr (chromium) or Ni (nickel).

One end portion (a right end portion in FIG. 4) of the vibrator element 6 in the α direction as described above is bonded to the third part 53 of the above-described relay substrate 5 via the two metal bumps 9. Here, the two metal bumps 9 are connected to two pad electrodes of the vibrator element 6. Note that, the arrangement of the metal bumps 9 is not limited to the arrangement illustrated in the drawing as long as the circuit element 4 and the vibrator element 6 can be electrically connected via the relay substrate 5. For example, the metal bump may be disposed at two corners at diagonal corners of the vibrator element 6, two metal bumps may be arranged at one corner of the vibrator element 6, or the metal bump may be disposed at each corner of the vibrator element 6.

### Metal Bump: Bonding Material

The metal bump 7 (first metal bump: first bonding material) bonds the base 2 (the package 10) and the circuit element 4 to each other. With this, it is possible to smoothly transfer heat between the base 2 and the circuit element 4, and as a result, it is possible to reduce the temperature difference between them. The metal bump 8 (second metal bump: second bonding material) bonds the circuit element 4 and relay substrate 5 to each other. With this, it is possible to smoothly transfer heat between the circuit element 4 and the relay substrate 5, and as a result, it is possible to reduce the temperature difference between them. The metal bump 9 (third metal bump: third bonding material) bonds the relay substrate 5 and the vibrator element 6 to each other. With this, it is possible to smoothly transfer heat between the relay substrate 5 and the vibrator element 6, and as a result, it is possible to reduce the temperature difference between them.

Each of the metal bumps 7, 8, and 9 has a circular shape in plan view. The shapes of the metal bumps 7, 8, and 9 are not limited to the shapes illustrated in the drawings, and may be, for example, a columnar shape, a polygonal columnar shape, or a circular truncated conical shape. The constituent materials of the metal bumps 7, 8, and 9 are not particularly limited, and examples thereof include metals such as gold (Au), silver (Ag), copper (Cu), aluminum (Al), and platinum (Pt), and an alloy thereof, a lead-free solder, a leaded solder, and the like. Each of the metal bumps 7, 8, and 9 can be formed by, for example, a plating method, a bonding method, or the like, and the bonding can be performed by pressure welding, heat pressing, or ultrasonic combined heating pressure welding or the like. Instead of at least a part of the metal bumps 7, 8, and 9, a conductive adhesive containing a resin material and a conductive filler may be used as a bonding material.

As described above, the vibrator device 1 includes the base 2, the circuit element 4 attached to the base 2, the vibrator element 6 attached to the circuit element 4 (via the relay substrate 5 in this embodiment), and the plurality of temperature sensors 41 arranged in the circuit element 4. In addition, the circuit element 4 includes a terminal 42 which is a first connecting terminal connected to the base 2, a terminal 43 which is a second connecting terminal connected to the vibrator element 6, an output buffer circuit 44, a power supply circuit 45, and a phase-locked loop circuit 46. The distance between each of the plurality of temperature sensors 41 and the terminal 42 or 43 which is the closest to each of the temperature sensors is shorter than the distance between each of the temperature sensors 41 and the circuit (any of the output buffer circuit 44, the power supply circuit 45, and the phase-locked loop circuit 46) which is the closest to each of the temperature sensors.

Note that, the distance between the terminal and the circuit may be set as the shortest distance among the distances between any of the sides or corners of the terminal and any of the sides or corners of any of the electronic components constituting the circuit. Regarding other temperature measurement accuracy, the distance may be appropriately determined in consideration of its influence.

In this manner, according to the vibrator device 1, the vibrator element 6 is attached to the circuit element 4 (attached via the relay substrate 5 in this embodiment), and thus it is possible to detect the temperature of the vibrator element 6 with high accuracy by using a temperature sensor 41 disposed in the circuit element 4. For this reason, the temperature compensation performance of the vibrator device 1 can be improved by using the detection result of the temperature sensor 41. In addition, since there are a plurality of the temperature sensors 41, it is possible to detect the temperature distribution of the circuit element 4 by using the plurality of temperature sensors 41 and perform more appropriate temperature compensation using the detection result. Further, when the temperature sensor 41 is disposed at a position closer to the terminals 42 and 43 than the output buffer circuit 44, the power supply circuit 45, and the phase-locked loop circuit 46 which are the heat sources in the circuit element 4, it is possible to further reduce the heat effect of the circuit element 4, and improve the temperature measurement accuracy of the vibrator element 6.

Here, at least two of the plurality of temperature sensors 41 (all the temperature sensors 41 in this embodiment) are arranged in the different positions from each other (that is, positions not overlapping with each other) when viewed from the direction (γ direction) where the circuit element 4 and the vibrator element 6 are arranged. With this, it is possible to detect the temperature distribution in the in-plane direction (direction along the αβ plane) of the circuit element 4. Therefore, more appropriate temperature compensation can be performed using the detection result.

In addition, the plurality of temperature sensors 41 include the temperature sensors 41a and 41b, which are first temperature sensors arranged on the active surface side (−γ direction side) of the circuit element 4, and the temperature sensor 41c which is the second temperature sensor disposed on the side (+γ direction side) opposite to the active surface side of the circuit element 4. As a result, it is possible to detect the temperature distribution (temperature gradient) in the thickness direction (γ direction) of the circuit element 4 based on the difference between the detected temperature of the temperature sensors 41a and 41b and the detected temperature of the temperature sensor 41c. Therefore, more appropriate temperature compensation can be performed using the detection result. Further, in this embodiment, the surface of the circuit element 4 on the side of the temperature sensor 41c faces the lid 3, and thus the temperature change of the circuit element 4 due to the heat from the lid 3 can be suitably detected using the temperature sensor 41c. Therefore, temperature compensation can be performed in consideration of radiation from the wall surface of the package 10 or heat due to convection.

The vibrator device 1 further includes the relay substrate 5 disposed between the vibrator element 6 and the circuit element 4, the metal bump 7 serving as a first bonding material bonding the base 2 and the circuit element 4, the metal bump 8 serving as the second bonding material bonding the circuit element 4 and the relay substrate 5, and the metal bump 9 serving as the third bonding material bonding the relay substrate 5 and the vibrator element 6. With this, the stress generated in the vibrator element 6 can be reduced. Therefore, it is possible to improve the characteristics such as the frequency-temperature characteristics of the vibrator device 1.

Here, the first bonding material, the second bonding material, and the third bonding material are respectively the metal bumps 7, 8, and 9. Consequently, heat conduction can be efficiently performed between the vibrator element 6 and the circuit element 4. For this reason, the temperature sensor 41 can be used to detect the temperature of the vibrator element 6 with higher accuracy. In addition, it is possible to mount the vibrator element 6 and the circuit element 4 on the package 10 without using a resin material. Therefore, even if a heat treatment is performed after the package 10 is sealed, it is possible to solve the problem caused by the gas (out gas) generated from the resin material in the package 10. Since the vibrator element 6 is supported by the circuit element 4 via the relay substrate 5, the stress generated in the vibrator element 6 can be reduced even with metal bumps.

The metal bump 7 (first bonding material) and the metal bump 8 (second bonding material) are disposed on the active surface side (−γ direction side) of the circuit element 4, and at least one of the plurality of temperature sensors 41 (the temperature sensors 41a and 41b in this embodiment) are arranged on the active surface side of the circuit element 4. As a result, there is no need to provide a structure like a Si through electrode in the circuit element 4, and cost reduction of the circuit element 4 can be achieved. Further, by using the temperature sensors 41a and 41b arranged on the active surface side of the circuit element 4, it is possible to detect the temperature of the vibrator element 6 with higher accuracy.

In addition, the metal bump 8 (second bonding material) is disposed on one surface side (+γ direction side) of the relay substrate 5, and the metal bump 9 (third bonding material) is disposed on the other surface side (−γ direction side) of the relay substrate 5. With this, the relay substrate 5 and the vibrator element 6 can be stacked and mounted on the circuit element 4 from the same side. Therefore, there is an advantage that these implementations are simplified.

### Second Embodiment

Next, a second embodiment of the invention will be described.

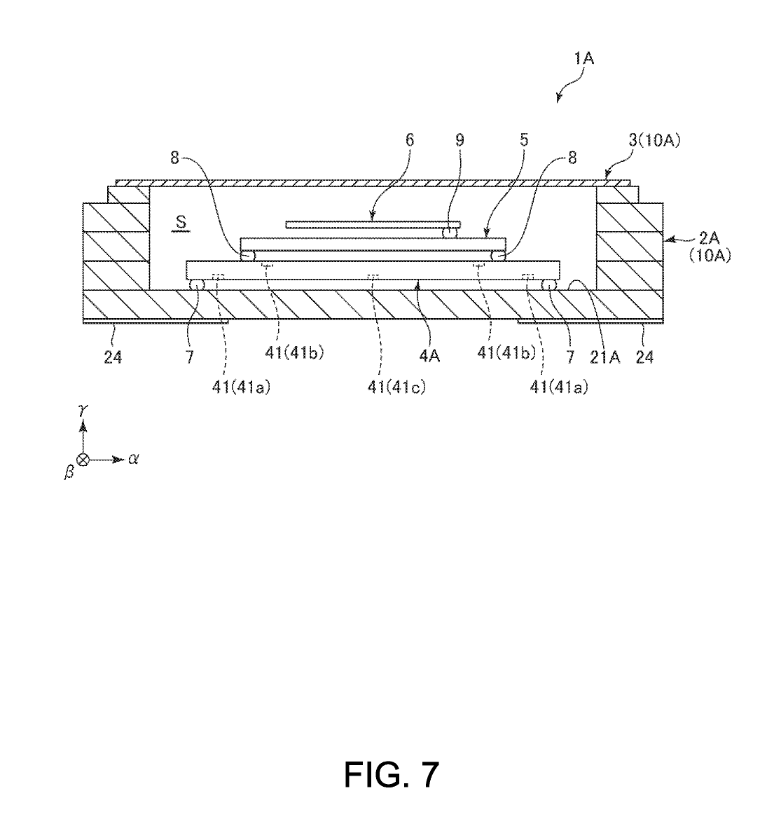

FIG. 7 is a longitudinal sectional view (a sectional view along an αγ plane) illustrating a vibrator device (oscillator) according to the second embodiment of the invention.

Hereinafter, the vibrator device of the second embodiment will be described focusing on differences from the above-described first embodiment, and description of similar items will not be made.

The vibrator device according to the second embodiment of the invention is the same as that in the above-described first embodiment except that the circuit element, the relay substrate, and the vibrator element are stacked in this order from the base side to the lid side of the package.

A vibrator device 1A illustrated in FIG. 7 is provided with a base 2A (base body), a lid 3, a circuit element 4A, a relay substrate 5, a vibrator element 6, metal bumps 7, 8, and 9.

Here, an opening of a recessed portion 21A of the base 2A is closed by the lid 3, and the base 2A and the lid 3 constitute a package 10A having a space S storing the circuit element 4A, the relay substrate 5, and the vibrator element 6. In the space S of this package 10A, the circuit element 4A, the relay substrate 5, and the vibrator element 6 are arranged (stacked) in this order from the −γ direction side to the +γ direction side.

The metal bump 7 (the first metal bump) bonds the base 2A and the circuit element 4A, and the circuit element 4A is attached to the base 2A via the metal bump 7. The metal bump 8 (the second metal bump) bonds the circuit element 4A and the relay substrate 5, and the relay substrate 5 is attached to the circuit element 4A via the metal bump 8. The metal bump 9 (the third metal bump) bonds the relay substrate 5 and the vibrator element 6, and the vibrator element 6 is attached to the relay substrate 5 via the metal bump 9.

Here, although not shown, a terminal to which the metal bump 7 is bonded is provided on the lower surface of the circuit element 4A; on the other hands, a terminal to which the metal bump 8 is bonded is provided on the upper surface of the circuit element 4A. In addition, the circuit element 4A is provided with electrodes such as a Si through electrodes for conducting between both surfaces of the circuit element 4A.

The circuit element 4A includes a plurality of temperature sensors 41. Here, the plurality of temperature sensors 41 include a plurality of temperature sensors 41a and a temperature sensor 41c arranged on the lower surface (active surface) side of the circuit element 4A, and a plurality of temperature sensors 41b arranged on the upper surface side of the circuit element 4A. As in the first embodiment, the plurality of temperature sensors 41a are provided corresponding to the plurality of metal bumps 7. The plurality of temperature sensors 41b are provided corresponding to the plurality of metal bumps 8 described above. The temperature sensor 41c is disposed at the center of the circuit element 4A in plan view. Here, in this embodiment, the plurality of temperature sensors 41b are arranged on the side opposite to the active surface side of the circuit element 4A, and the temperature sensor 41c is disposed on the active surface side of the circuit element 4A.

According to the second embodiment as described above, as in the above-described in the first embodiment, the vibrator element 6 is attached to the circuit element 4A (attached via the relay substrate 5 in this embodiment), and thus it is possible to detect the temperature of the vibrator element 6 with high accuracy by using a temperature sensor 41 disposed in the circuit element 4A. For this reason, the temperature compensation performance of the vibrator device LA can be improved by using the detection result of the temperature sensor 41. In addition, since there are a plurality of the temperature sensors 41, it is possible to detect the temperature distribution of the circuit element 4A by using the plurality of temperature sensors 41 and perform more appropriate temperature compensation using the detection result.

In addition, in the vibrator device 1A of this embodiment, one (the metal bump 7 in this embodiment) of the metal bump 7 (first bonding material) and the metal bump 8 (second bonding material) is disposed on the active surface side of the circuit element 4A, and the other one (the metal bump 8 in this embodiment) is disposed on the side opposite to the active surface side of the circuit element 4A. In addition, at least one (the temperature sensor 41b in this embodiment) of the plurality of temperature sensors 41 is disposed on the metal bump 8 (the second bonding material) side of the circuit element 4A. With this, the circuit element 4A and the relay substrate 5 can be stacked and mounted on the package 10A from the same side. Therefore, there is an advantage that these implementations are simplified. Further, by using the temperature sensors 41b arranged on the metal bump 8 side of the circuit element 4A, it is possible to detect the temperature of the vibrator element 6 with higher accuracy.

### Electronic Apparatus

Next, an electronic apparatus according to the invention will be described.

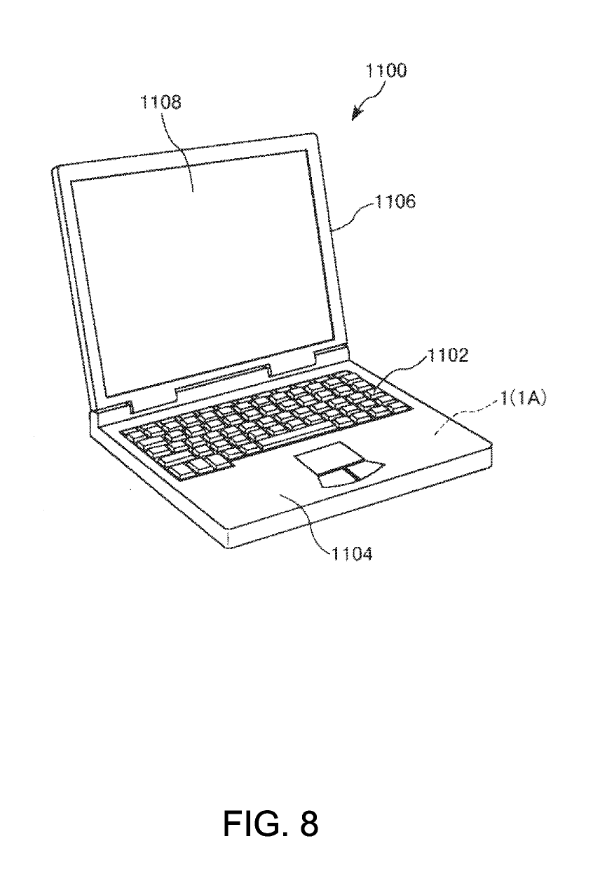

FIG. 8 is a perspective view illustrating a configuration of a mobile type (or notebook type) personal computer which is an example of an electronic apparatus according to the invention. In FIG. 8, a personal computer 1100 is configured to include a main body portion 1104 provided with a keyboard 1102 and a display unit 1106 provided with a display portion 1108, and the display unit 1106 is configured to be pivotably supported around the main body portion 1104 via a hinge structure portion. A vibrator device 1 (or LA) functioning as a filter, a resonator, a reference clock, or the like is built in the aforementioned personal computer 1100.

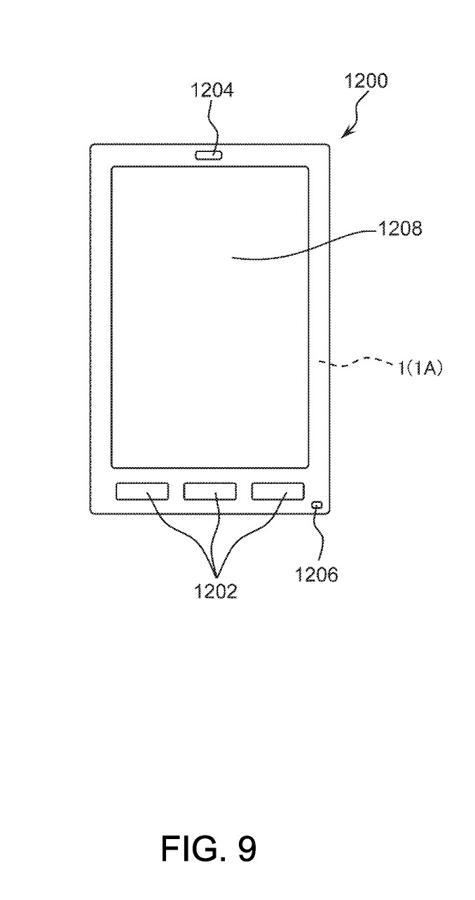

FIG. 9 is a perspective view illustrating a configuration of a smartphone which is an example of the electronic apparatus according to the invention. In FIG. 9, a mobile phone 1200 is provided with a plurality of operation buttons 1202, an earpiece 1204, and a mouthpiece 1206, and a display portion 1208 is disposed between the operation button 1202 and the earpiece 1204. A vibrator device 1 (or 1A) functioning as a filter, a resonator, or the like is built in the aforementioned mobile phone 1200.

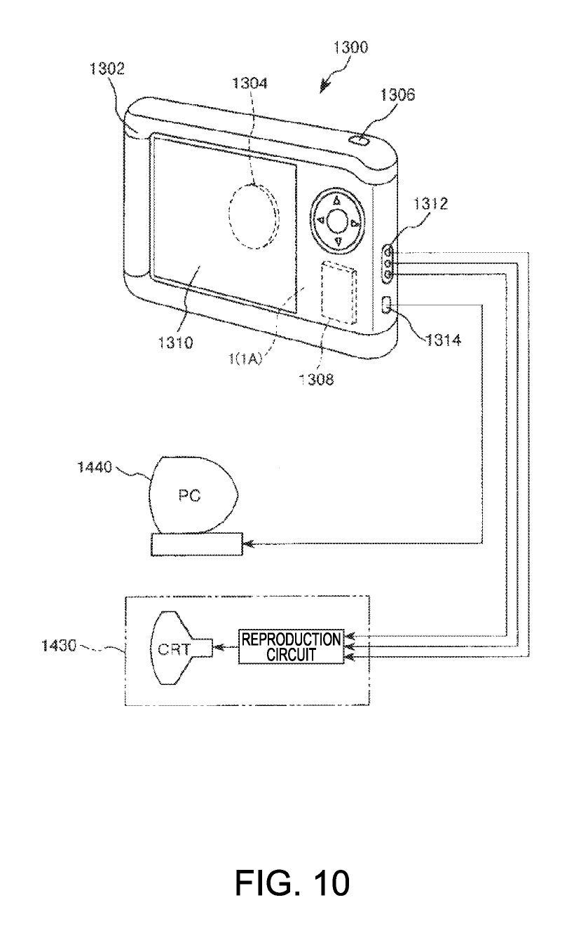

FIG. 10 is a perspective view illustrating a configuration of a digital still camera which is an example of the electronic apparatus according to the invention. Note that connection with an external device is also briefly illustrated in FIG. 10. A display portion 1310 is provided on a rear surface of a case (body) 1302 of the digital still camera 1300, and is configured to perform display based on imaging signals of the CCD, and the display portion 1310 functions as a viewfinder displaying a subject as an electronic image. A light receiving unit 1304 including an optical lens (imaging optical system) and a CCD or the like is provided on the front side (back side in the drawing) of the case 1302.

When the photographer confirms a subject image displayed on the display portion 1310 and presses a shutter button 1306, the imaging signal of the CCD at that time is transferred and stored in a memory 1308. In the digital still camera 1300, a video signal output terminal 1312 and an input and output terminal 1314 for data communication are provided on the side surface of the case 1302. As illustrated in FIG. 10, a television monitor 1430 is connected to the video signal output terminal 1312, and a personal computer 1440 is connected to the input and output terminal 1314 for data communication, as necessary. Further, the imaging signal stored in the memory 1308 is output to the television monitor 1430 or the personal computer 1440 by a predetermined operation. A vibrator device 1 (or 1A) functioning as a filter, a resonator, or the like is built in the aforementioned digital still camera 1300.

The above-described electronic apparatus is provided with the vibrator device 1 or 1A. According to such an electronic apparatus, the characteristics of the electronic apparatus can be improved by using excellent characteristics of the vibrator device 1 or 1A.

Note that, the electronic apparatus provided with the vibrator device according to the invention can be applied to, for example, a watch, a tablet terminal, an ink jet type discharging apparatus (for example, an ink jet printer), a laptop personal computer, TV, a video camera, a video tape recorder, a car navigation device, a pager, an electronic notebook (including a communication function), an electronic dictionary, a calculator, an electronic game machine, a word processor, a work station, a video phone, a security TV monitor, electronic binoculars, a POS terminal, medical equipment (such as an electronic clinical thermometer, a blood pressure monitor, a blood glucose meter, an electrocardiogram measuring device, an ultrasonic diagnostic device, and an electronic endoscope), a fish finder, various measuring instruments, meters and gauges (such as meters and gauges for a vehicle, an aircraft, and a ship), a flight simulator, in addition to the personal computer (mobile type personal computer) of FIG. 8, the smartphone (mobile phone) of FIG. 9, and the digital still camera of FIG. 10.

### Vehicle

Next, a vehicle (vehicle according to the invention) to which the vibrator device according to the invention is applied will be described.

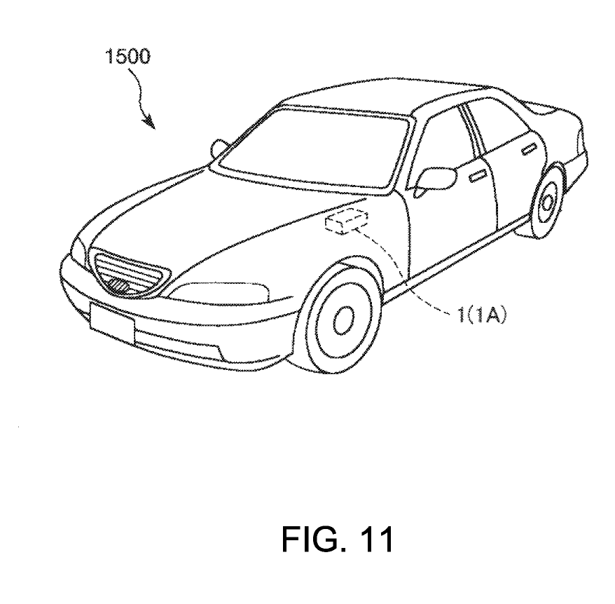

FIG. 11 is a perspective view illustrating an automobile which is an example of the vehicle according to the invention. A vibrator device 1 (or 1A) is mounted on an automobile 1500. The vibrator device 1 or 1A can be applied to an electronic control unit (ECU) such as keyless entry, an immobilizer, a car navigation system, a car air conditioner, an anti-lock brake system (ABS), an air bag, a tire pressure monitoring system (TPMS), engine control, a battery monitor of a hybrid car and an electric vehicle, and a vehicle body attitude control system.

The automobile 1500 which is the above-described vehicle is provided with the vibrator device 1 or 1A. According to such an automobile 1500, the characteristics of the automobile 1500 can be improved by using excellent characteristics of the vibrator device 1 or 1A.

Although the vibrator device, the electronic apparatus, and the vehicle according to the invention have been described based on the embodiments illustrated in the drawings; however, the invention is not limited thereto, and the configuration of each portion can be replaced by optional configuration having the same functions. Further, any other constituent may be added to the invention. Further, each of the above-described embodiments may be appropriately combined.

In the above-described embodiment, the quartz crystal substrate is used as a piezoelectric substrate, but various kinds of piezoelectric substrates such as lithium niobate and lithium tantalate may be used instead.

Further, in the above-described embodiment, a configuration in which a member such as a relay substrate is disposed between the circuit element and the vibrator element has been described; however, the invention is not limited thereto, and the circuit element and the vibrator element may be bonded together with the bonding material such as the metal bump without some members such as the relay substrate.

Further, in the above-described embodiments, a case where the vibrator element is an element that causes thickness sliding vibration is described as an example; however, the invention is not limited thereto, and may be a tuning fork type vibrator or the like, for example. Further, in the above-described embodiments, a case where the vibrator device is an oscillator is described as an example, but the invention is not limited thereto, and the invention can also be applied to, for example, a gyro sensor and the like.

The entire disclosure of Japanese Patent Application No. 2017-247353, filed Dec. 25, 2017 is expressly incorporated by reference herein.

What is claimed is:

1. A vibrator device comprising:
a base;
a circuit element attached to the base;
a vibrator element attached to the circuit element; and
a plurality of temperature sensors arranged in the circuit element,
wherein the circuit element includes
a first connecting terminal connected to the base,
a second connecting terminal connected to the vibrator element, and
at least one circuit of an output buffer circuit, a power supply circuit, and a phase-locked loop circuit, and
wherein the shortest distance between each of the plurality of temperature sensors and the first connecting terminal or the second connecting terminal is shorter than the shortest distance between each of the temperature sensors and the at least one circuit.

2. The vibrator device according to claim 1,
wherein at least two of the plurality of temperature sensors are arranged at different positions when viewed from a direction in which the circuit element and the vibrator element are arranged.

3. The vibrator device according to claim 1,
wherein the plurality of temperature sensors include
a first temperature sensor disposed on an active surface side of the circuit element, and
a second temperature sensor disposed on a side opposite to the active surface side of the circuit element.

4. The vibrator device according to claim 1, further comprising:
a relay substrate disposed between the vibrator element and the circuit element;
a first bonding material that bonds the base and the circuit element to each other;
a second bonding material that bonds the circuit element and the relay substrate to each other; and
a third bonding material that bonds the relay substrate and the vibrator element to each other.

5. The vibrator device according to claim 4,
wherein each of the first bonding material, the second bonding material, and the third bonding material is a metal bump.

6. The vibrator device according to claim 4,
wherein the first bonding material and the second bonding material are disposed on the active surface of the circuit element, and
wherein at least one of the plurality of temperature sensors is disposed on the active surface of the circuit element.

7. The vibrator device according to claim 4,
wherein one of the first bonding material and the second bonding material is disposed on the active surface of the circuit element, and the other one is disposed on a surface opposite to the active surface of the circuit element, and
wherein at least one of the plurality of temperature sensors is disposed on the second bonding material side of the circuit element.

8. The vibrator device according to claim 4,
wherein the second bonding material is disposed on one surface of the relay substrate, and
wherein the third bonding material is disposed on the other surface of the relay substrate.

9. An electronic apparatus comprising the vibrator device according to claim 1.

10. A vehicle comprising the vibrator device according to claim 1.
